(19) United States
(12) Patent Application Publication
(10) Pub. No.: US 2008/0191583 A1
(43) Pub. Date: Aug. 14, 2008

(54) Linear drive and method for displacing an object by a linear drive

(75) Inventor: Robert Bohn, Schriesheim (DE)

Correspondence Address: SIEMENS CORPORATION;INTELLECTUAL PROPERTY DEPARTMENT, 170 WOOD AVENUE SOUTH, ISELIN, NJ, 08830, US

(73) Assignee: SIEMENS AKTIENGESELLSCHAFT

(21) Appl. No.: 12/011,222

(22) Filed: Jan. 24, 2008

(30) Foreign Application Priority Data
Jan. 25, 2007 (DE) 10 2007 003 853.6
Jan. 29, 2007 (DE) 10 2007 004 307.6
Jan. 10, 2008 (DE) 10 2008 003 879.2

(51) Int. Cl. H02N 2/02; H01L 41/09

(52) U.S. Cl. 310/329; 310/354; 318/116

(57) ABSTRACT

A linear drive for driving a moveably mounted object comprises at least one piezoelectric actuator that can be driven by a control device. The piezoelectric actuator has a piezoelectric element held by a holding body and a transducer coupled to said element. A mechanical frictional engagement is embodied for transmitting a driving force between the transducer and the object requiring to be moved. The control device controls the piezoelectric actuator in such a way that, exploiting the mass inertia of the object, the object will be moved compliantly by the transducer during an excursion of the piezoelectric element in the direction of motion and, in the opposite direction, the transducer will slide across the object. A simple and economic linear drive is realized in that way. The transducer is coupled purely passively by the frictional engagement. It is not necessary to provide an additional device for coupling.

### CROSS REFERENCE TO RELATED APPLICATIONS

This application claims priority of German application No. 10 2007 003 853.6 filed Jan. 25, 2007 and priority of German application No. 10 2007 004 307.6 filed Jan. 29, 2007, and priority of German application No. 10 2008 003 879.2 filed Jan. 10, 2008, which are incorporated by reference herein in their entirety.

### FIELD OF THE INVENTION

The invention relates to a linear drive, a drive unit for embodying a linear drive and a method for displacing an object by means of a linear drive.

### BACKGROUND OF THE INVENTION

Principally employed according to the prior art as linear drives or as drive systems having linearly moved elements are direct drives based on electromagnetic stepping motors as well as hydraulic and pneumatic actuators. Further known are linear drives wherein a linear movement is produced indirectly with the aid of mechanical transmission elements. Thus in the case of a spindle drive a rotational movement is converted into a linear movement indirectly by means of a spindle coupled to a three-phase a.c. motor. Said linear drives are all more or less mechanically complex. Moreover, a sophisticated control or regulating system is necessary in each case for producing the linear movement.

Known from DE 198 53 324 A1 and DE 100 46 137 A1 is in each case a linear drive having movement-producing actuators and passive elements moveable thereby. The passive elements are therein coupled magnetically, electrostatically, or mechanically to the surface of an object requiring to be moved. For transmitting a movement, the controllable frictional force between the passive elements and the object is greater than the inertial force engaging on the object.

Known from DE 102 27 509 A1 with regard particularly to miniaturizing a linear drive is a piezoelectric motor that can be used as a linear drive. For that purpose the piezoelectric motor has a piezoelectric element connected to a resonator. The resonator is made to periodically oscillate by means of the piezoelectric element, causing the end of the resonator to move. While the piezoelectric motor is operating, the end of the resonator presses periodically against an element requiring to be moved. Said element requiring to be moved is embodied as a linear inductor and mounted longitudinally displaceably so that a linear movement can be produced by means of the piezoelectric motor.

### SUMMARY OF THE INVENTION

The object of the invention is to disclose a linear drive that is simple and economical to produce. Said linear drive is furthermore to be implemented based on piezoelectric technology to enable the advantages thereof to be used.

Said object is inventively achieved by means of a linear drive for driving a moveable object as claimed in the claims. The linear drive for that purpose includes at least one piezoelectric actuator that can be driven by a control device. The piezoelectric actuator has a piezoelectric element held by a holding body as well as a transducer coupled to said element. Embodied between the transducer and object requiring to be moved is a mechanical frictional engagement for transmitting a driving force. The control device drives the piezoelectric actuator in such a way that, exploiting the object's mass inertia, the object will be moved compliantly during an excursion in the direction of motion and, in the opposite direction, the transducer will slide across the object. In other words, when frictional contact has been established with the transducer the displaceably mounted object will be moved thereby by means of static friction. The mechanical coupling between the transducer and the object by means of frictional engagement is purely passive in nature. There is hence no need to control the coupling force. Because the transducer is linked directly to the displaceably mounted object by means of frictional engagement there is no mechanical play whatever between the transducer and the object. A particularly high degree of positioning and repetition accuracy can hence be achieved. A complex control system for compensating positioning inaccuracies of the kind needed even for highly accurate stepping motors does not have to be employed. The piezoelectric element's expansion is moreover proportional to a supply voltage applied thereto. Via the supply voltage it is thus possible to specify precisely and simply how far the transducer secured to the piezoelectric element will be displaced and how far the transducer will hence displace the object by means of frictional engagement. A successive linear movement of the object can thus be achieved by driving the piezoelectric element repeatedly.

A piezoelectric actuator requires only little structural space. The linear drive can therefore have very small dimensions. It can hence be advantageously employed also in miniaturized form. Because force is transmitted directly to the object requiring to be moved by means of the transducer via frictional engagement it is further possible to dispense with gearing for the transmitting of force so that the drive can be implemented simply and economically. The piezoelectric element expands virtually without sound so that very little noise is produced while the object is being moved. Moreover, the current consumption of the piezoelectric element and hence of the piezoelectric actuator is low while the transducer is being moved, but especially while the object is being held in a holding position by means of frictional engagement. A transformer for electrically powering the piezoelectric actuator will hence require only little power. The energy requirements of the piezoelectric actuator and hence of the linear drive are therefore low, with the result that the operating costs of the linear drive are low compared with a motor-driven linear drive. The noise produced while the transformer is operating is moreover low owing to the low power consumption.

The control unit is advantageously set up for driving the piezoelectric actuator in such a way that the transducer's speed will be lower in the direction of motion than in the opposite direction. Rapid buildup or cleardown of the supply voltage will cause the piezoelectric element to expand or contract rapidly. The transducer secured to the piezoelectric element will thus overcome the static frictional force being applied to its friction surface through frictional engagement. The transducer will be moved in the direction counter to the direction of motion by means of sliding friction on the surface of the object requiring to be moved. The transducer's contact point on the object can be changed in that way. What is therein exploited is that the object requiring to be moved has a significantly greater mass than the transducer and so will retain its position owing to its mass inertia.

Slow buildup or cleardown of the supply voltage will cause the piezoelectric element to expand or contract slowly. A frictional engagement between the transducer and object will be produced in that way. The object's mass inertia will be overcome by the static frictional force between the transducer and object. The object will be displaced in the direction of motion by means of the transducer engaging on it.

Thus a linear movement of the object in the direction of motion can be achieved in a simple manner with a periodic supply voltage that rises rapidly and falls slowly. A reversal of the direction of motion can be achieved just as simply with a periodic supply voltage that falls rapidly and rises slowly.

A bilateral linear movement can accordingly be implemented using an asymmetric supply voltage. For example a periodic voltage having the nature of an asymmetric sawtooth is suitable as the supply voltage.

In an advantageous development a plurality of piezoelectric actuators are provided for moving the object. Thus an object having a high mass and hence a high mass inertia can also be moved by means of the linear drive. The piezoelectric actuators can be moved jointly by means of the control device so that the static frictional force transmitted to the object by means of static friction will suffice to displace it by means of frictional engagement.

The control device is advantageously set up for operating the piezoelectric actuators in succession. That will enable the individual transducers' contact points to be changed successively by means of sliding friction exploiting the object's mass inertia and allow the object to be displaced continuously without interruption.

In an advantageous variant the control device is set up for operating the same number of transducers in the direction of motion or a higher number thereof than in the opposite direction. Only as many transducers are ever moved jointly for repositioning the transducers for the object not, owing to its mass inertia, to undergo any displacement due to the frictional force engaging thereon. Displacing of the transducers' contact points can, moreover, be supported by a rapid buildup or cleardown of the supply voltage engaging on the piezoelectric elements. By driving the same or a higher number of transducers the object is then displaced by means of static friction and its mass inertia hence overcome.

In an expedient development a linear guide for guiding the transducer is located between the holding body and transducer. Said linear guide is embodied as, for example, a roller bearing or ball bearing. Moving of the transducer against the holding body by means of the piezoelectric element will in that way be guided. The transducer can be positioned especially precisely thereby. A linear guide can furthermore be implemented in the manner of a roller bearing or in the manner of a ball bearing simply and economically.

The transducer is advantageously pretensioned against the holding body by means of an elastic element in such a way that pretensioning will be increased if the frictional body moves against the elastic element. The elastic element can be embodied in the manner of, for instance, a leaf spring encompassing the transducer preferably on its front side opposite the piezoelectric element. If the supply voltage being applied to the piezoelectric element is reduced, then the transducer will not only be pulled longitudinally by the piezoelectric element but also pushed toward the piezoelectric element by means of the elastic element. Moving of the transducer will be additionally supported and guided thereby. It will thus be possible to realize especially precise movements of the object that exhibit little play.

In an advantageous development the holding body encompasses the piezoelectric element with the transducer like a clamp. Especially good guiding of the transducer will be achieved thereby.

The object is further achieved by means of a drive unit for embodying a linear drive as claimed in one of the preceding claims. The drive unit for that purpose includes at least one piezoelectric actuator that can be driven by a control device. The piezoelectric actuator has a piezoelectric element and a transducer coupled thereto. The transducer is embodied as a frictional body for embodying a frictional engagement and transmitting a driving force to an object requiring to be moved. The control device is embodied for driving the piezoelectric actuator variously dependent on direction in order to move the object in a direction of motion only, exploiting its mass inertia. The claims directed to the linear drive along with their advantages are therein applicable analogously to the drive unit.

The object is further achieved by means of a method for displacing an object by means of a linear drive as claimed in the claims. The linear drive has at least one piezoelectric actuator having a piezoelectric element as well as a transducer coupled to the piezoelectric element. A driving force is transmitted between the transducer and the object by means of a mechanical frictional engagement. The piezoelectric actuator is therein driven in such a way that, exploiting the object's mass inertia, the object will be moved compliantly by the transducer in the direction of motion and, in the opposite direction, the transducer will slide across the object. The claims directed to the linear drive along with their advantages are therein applicable analogously to the method.

### BRIEF DESCRIPTION OF THE DRAWINGS

An exemplary embodiment of the invention is explained in more detail below with reference to a drawing, in which:

FIG. 1 is a schematic side view of a first linear drive having a piezoelectric actuator for moving an object,

FIGS. 2a-c are schematics of the object's movement in two phases in a direction of motion by means of a linear drive and in a time-voltage chart for the piezoelectric actuator's supply voltage,

FIGS. 3a-c show the object's movement by means of the linear drive counter to the direction of motion shown in FIG. 2 likewise in two phases and in a time-voltage chart for the piezoelectric actuator's supply voltage,

FIGS. 4a-c show an object's linear movement in three phases by means of a second linear drive having two piezoelectric actuators in a direction of motion,

FIGS. 5a-c show the object's movement shown in FIG. 4 likewise in three phases counter to the direction of motion shown in FIG. 4,

FIGS. 6a-c show an object's movement in three phases in a direction of motion by means of a third linear drive having two piezoelectric actuators located on a side of the object, and

FIGS. 7a-c show the object's movement shown in FIG. 6 likewise in three phases counter to the direction of motion shown FIG. 6.

### DETAILED DESCRIPTION OF THE INVENTION

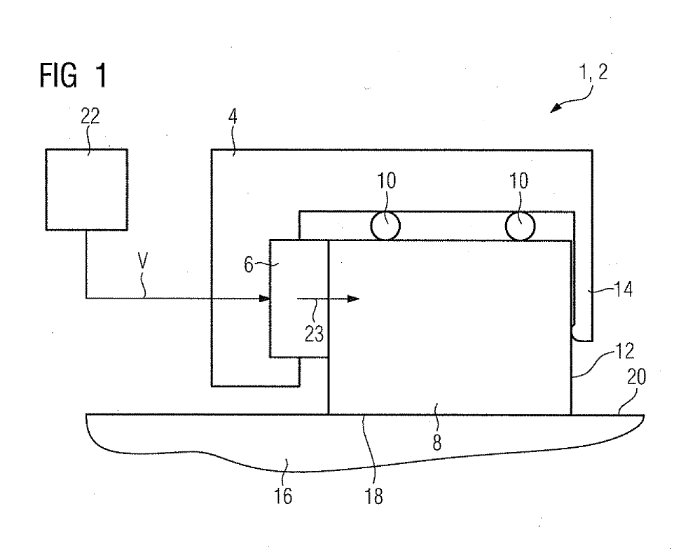

FIG. 1 shows a first linear drive 1 that includes a piezoelectric actuator 2. The piezoelectric actuator 2 has a static holding body 4 for accommodating a piezoelectric element 6. A transducer 8 is secured longitudinally displaceably on the piezoelectric element 6. The transducer 8 is mounted against the static holding body 4 by means of a linear guide 10. The linear guide 10 includes two cylindrical roll bodies. The transducer 8 is furthermore held in a pretensioned way at its front side 12 situated opposite the piezoelectric element 6 by an elastic element 14 that is embodied in the manner of a leaf spring and integrated in the holding body 4. With its elastic element 14 the holding body 4 therein encompasses the piezoelectric element 2 with the transducer 8 like a clamp.

The transducer 8 is in frictional contact with an object 16 requiring to be moved. The frictional contact is therein formed by a friction surface 18 located on the transducer and the surface of the object 16 embodied likewise as a friction surface 20.

The piezoelectric element 6 is driven by means of a control device 22 through specifying a supply voltage V. The piezoelectric element 6 therein expands in its expansion direction 23 as the supply voltage V increases. The transducer 8 secured to the piezoelectric element 6 is thus moved in the longitudinal direction 23 against the elastic element 14. The spring tension of the elastic element 14 increases successively.

If, on the other hand, the supply voltage V of the piezoelectric element 6 is reduced by the control device 22, then the expansion of the piezoelectric element 6 will be reduced. The transducer secured to the piezoelectric element 6 will be pulled by the piezoelectric element 6 counter to its expansion direction 23. The spring tension of the elastic spring element 14 will therein be reduced. The elastic element 14 and the linear guide 10 support guiding of the transducer 8 in the expansion direction 23 and in the direction counter thereto.

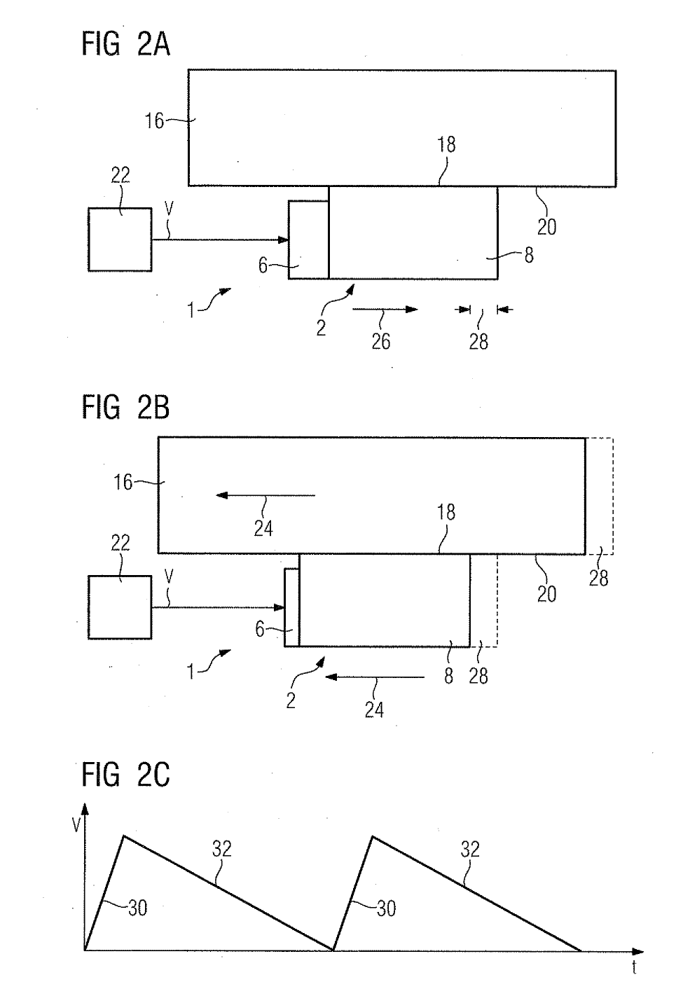

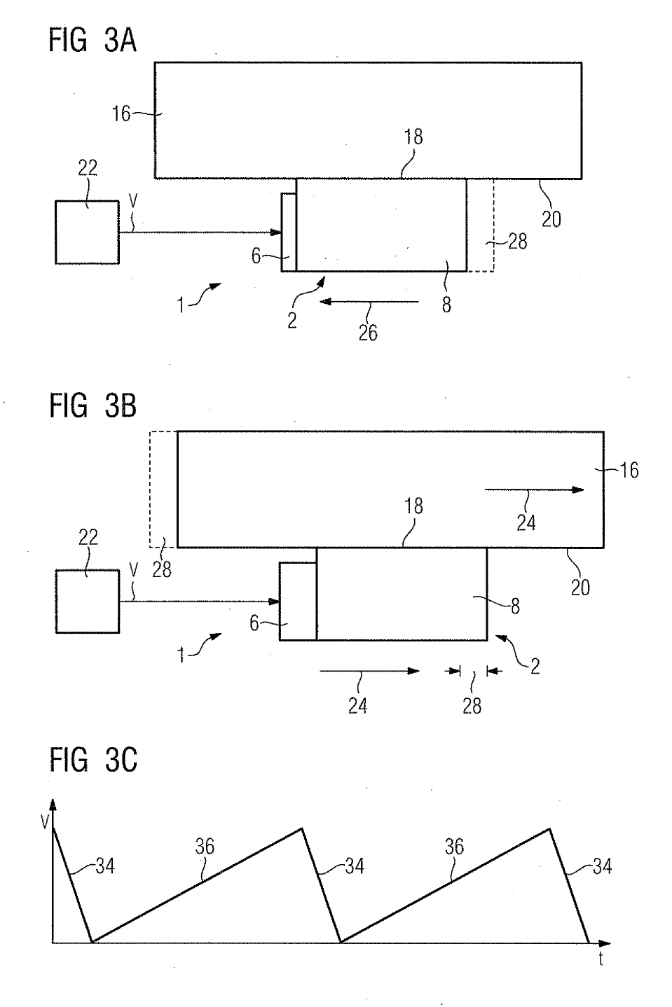

Moving of the object 16 by means of the linear drive 1 in a direction of motion 24 parallel to the expansion direction 23 of the piezoelectric element 6 is explained in FIGS. 2 and 3. Of the piezoelectric actuator 2 only its piezoelectric element 6 and its transducer 8 secured to the piezoelectric element 6 are shown for simplicity's sake. For moving the object in the direction of motion 24 the supply voltage V of the piezoelectric element 6 is according to FIG. 2a first rapidly increased by means of the control device 22. The piezoelectric element 6 expands in the direction 26 counter to the direction of motion 24. Since said expanding takes place quickly, the frictional force prevailing between the transducer 8 and the object 16 will be overcome. The transducer 8 is moved by means of sliding friction along the surface of the object 16. The travel interval 28 is therein covered in the opposite direction 26. The transducer 8 thus changes its contact point on the object 16 by the extent of the travel interval 28.

The supply voltage V of the piezoelectric element 6 is then reduced according to FIG. 2b by means of the control device 22. Said reduction in the supply voltage V takes place slowly. The piezoelectric element 6 retracts in the direction of motion 24. The transducer 8 is pulled by the piezoelectric element 6 in the direction of motion 24 by the extent of the travel interval 28. Since said pulling of the transducer 8 takes place slowly, a frictional engagement will be established via static friction between the transducer 8 and the object 16. The object 16 will hence be moved compliantly by means of static friction by the transducer 8 in the direction of motion 24 by the extent of the travel interval 28.

The contact point of the transducer 8 on the object 16 is again according to FIG. 2a then changed. The object 16 is again according to FIG. 2a then moved in the direction of motion 24 by the extent of the travel interval 28. That will produce a continuous linear movement of the object 16 in the direction of motion 24.

The supply voltage V engaging on the piezoelectric element 6 is shown in FIG. 2c as a function of time. The curve of the supply voltage V has in time terms the nature of an asymmetric sawtooth. The rapid increase in the supply voltage V according to FIG. 2 corresponds to the steeply rising first edge 30 of the sawtooth. The slow drop in the supply voltage V of the piezoelectric element 6 according to FIG. 2b corresponds to the slowly falling edge 32 of the sawtooth. According to FIG. 2b the object 16 is moved in the direction of motion 24 each time the sawtooth falls slowly. A continuous linear movement of the object 16 in the direction of motion 24 will hence have been achieved through specifying the periodic sawtooth voltage as the supply voltage V of the piezoelectric element 6.

Moving of the object 16 by means of the linear drive 1 in the direction of motion 24 counter to the direction of motion shown in FIGS. 2a-c is described in FIGS. 3a-c. According to FIG. 3a the supply voltage V is rapidly reduced when the piezoelectric element 6 is fully expanded by means of the control device 22. The transducer 8 is pulled by the piezoelectric element 6 in the direction 26 counter to the direction of motion 24. Since said pulling takes place rapidly, the adhesive force between the transducer 8 and the object 16 will be overcome. By means of sliding friction the transducer 8 will be moved by the extent of the travel interval 28 in the opposite direction 26 on the surface of the object 16. The contact point of the transducer 8 will hence change.

The supply voltage V of the piezoelectric element 6 is then according to FIG. 3b successively and slowly increased by means of the control device 22. The piezoelectric element 6 expands slowly in the direction of motion 24. Since said expanding of the transducer 8 takes place slowly, there will be frictional engagement between the transducer 8 and the object 16. The object 16 is moved along with the transducer 8 by the extent of the travel interval 28 in the direction of motion 24. The movement curve is then according to FIG. 3a continued to produce a continuous linear movement in the direction of motion 24.

The supply voltage V engaging on the piezoelectric element 6 is shown in FIG. 3c as a function of time. Its curve again has the nature of an asymmetric sawtooth. The supply voltage V is first rapidly reduced by means of the control device 22. That corresponds in terms of the time curve of the supply voltage V to a steeply falling edge 34 of the sawtooth. The supply voltage V is then slowly increased by means of the control device 22. That corresponds to a slowly rising edge 36 of the sawtooth. A continuous linear movement of the object 16 in the first longitudinal direction 24 will hence have been achieved through specifying the periodic sawtooth voltage as the supply voltage V of the piezoelectric element 6.

A linear movement in both directions is overall possible according to FIGS. 2a-c and FIGS. 3a-c by means of two asymmetric sawtooth voltages.

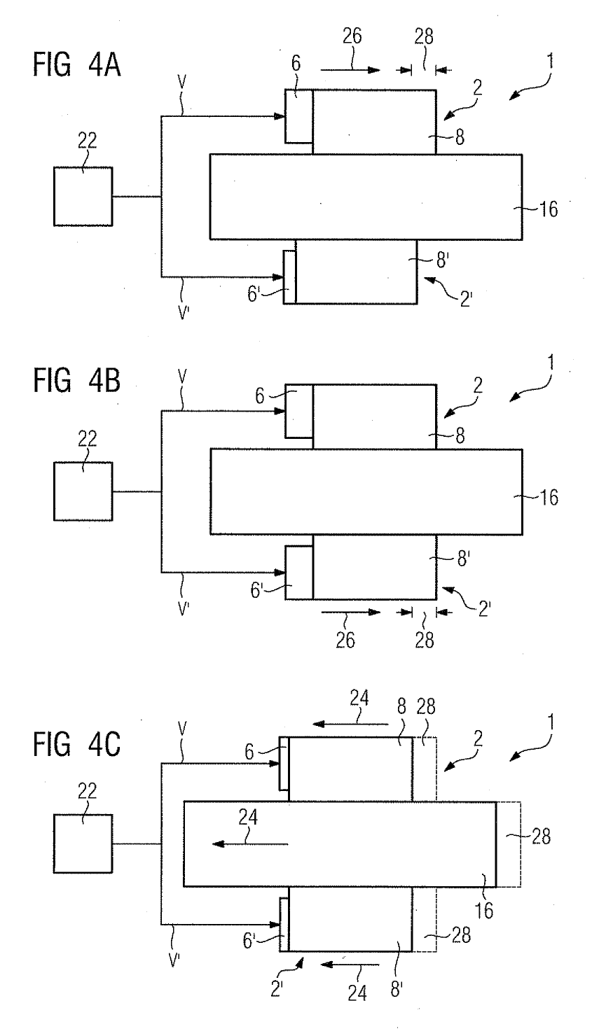

Only objects 16 having a relatively low mass 16 can be moved by means of an individual piezoelectric actuator. Two or more piezoelectric actuators 2 can, though, also be combined into a single linear drive. According to FIG. 4a, two piezoelectric actuators 2,2′ form a linear drive for displacing an object 16. The transducers 8,8′ of the piezoelectric actuators 2,2′ are both in frictional contact with the opposite flat sides of the object 16. The way the object 16 is displaced in the second longitudinal direction 26 is substantially the same as described in FIGS. 2a to 2c. The supply voltage V of the piezoelectric element 6 of the first piezoelectric actuator 2 is first rapidly increased by means of the control device 22. The transducer 8 of the piezoelectric actuator 2 slides by means of sliding friction across the object's surface 16. It therein covers the travel interval 28 in the direction 26 counter to the direction of motion 24 and thus changes its contact point. The supply voltage V′ of the piezoelectric element 6′ is then rapidly increased according to FIG. 4b by means of the control device 22. The transducer 8′ of the piezoelectric actuator 2′ will thus also be displaced in the opposite direction 26 on the surface of the object 16 by the extent of the travel interval 28. The transducers 8,8′ of both piezoelectric actuators 2,2′ will then both have a new contact point displaced in the opposite direction 26 by the extent of the travel interval 28.

The supply voltages V,V′ of the two piezoelectric elements 6,6′ are according to FIG. 4c finally slowly simultaneously reduced by means of the control device 22. The transducers 8,8′ are both moved by the piezoelectric elements 6,6′ in the direction of motion 24 by the extent of the travel interval 28. Thus the frictional forces of both friction surfaces 18 of the transducers 8,8′ will engage jointly via frictional engagement on the object 16. Since both transducers 8,8′ are, moreover, moved slowly, the object 16 will by means of frictional engagement also be moved compliantly with the transducers 8,8′ in the direction of motion 24 by the extent of the travel interval 28. The contact point of both transducers 8,8′ is then in turn changed again as described for FIGS. 4a and 4b. A continuous linear movement of the object 16 in the direction of motion 24 will have been achieved thereby.

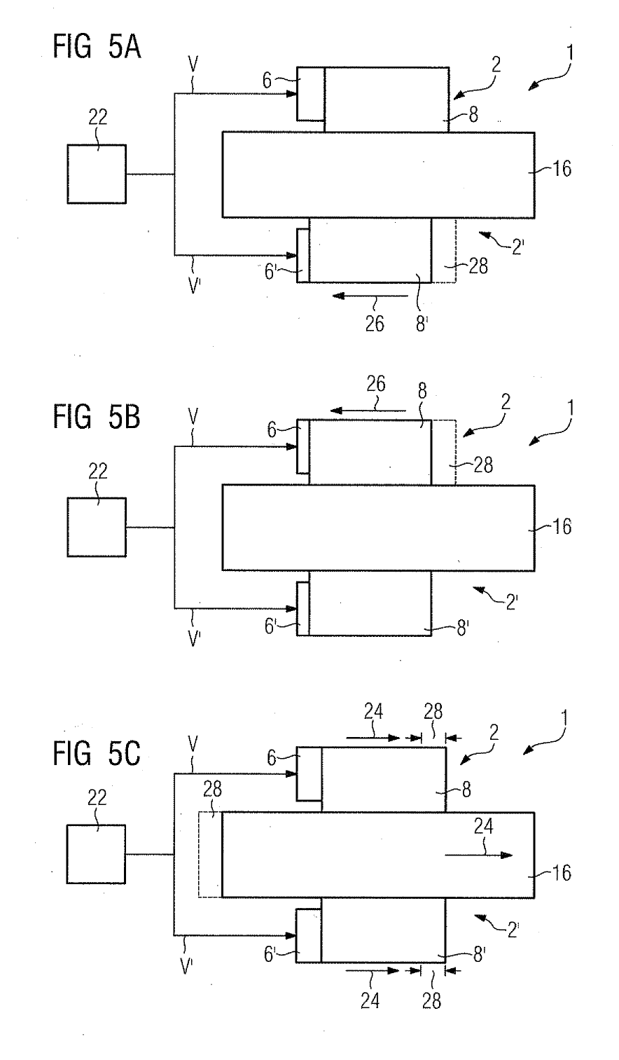

Described in FIGS. 5a-c is the movement of the object 16 by means of the second linear drive 1 in the direction of motion 24 counter to the direction of motion shown in FIGS. 4a-c. The object 16 is moved in a manner analogous to that described for an individual piezoelectric actuator 2 in FIGS. 3a to 3c. According to FIG. 5a the supply voltage V of the piezoelectric element 6′ is first reduced rapidly by means of the control device 22. The transducer 8′ of the piezoelectric actuator 2′ moves by the extent of the travel interval 28 in the direction 26 counter to the direction of motion 24. According to FIG. 5b the supply voltage V of the piezoelectric element 6 of the first piezoelectric actuator 2 is then reduced by means of the control device 22. The transducer 8 of the piezoelectric actuator 2 hence also moves by means of sliding friction by the extent of the travel interval 28 in the opposite direction 26. The contact point of both transducers 8,8′ of both piezoelectric actuators 2,2′ will hence in each case have been changed by the extent of the travel interval 28.

According to FIG. 5c the supply voltages of the two piezoelectric actuators 6,6′ are finally slowly simultaneously increased by means of the control device 22. The transducers 8,8′ are both displaced in the direction of motion 24 by the extent of the travel interval 28. Because said displacement takes place slowly and, moreover, both friction surfaces of both transducers 8,8′ transmit a frictional force to the object 16 by means of frictional engagement, the object 16 will likewise be moved by means of static friction in the direction of motion 24 by the extent of the travel interval 28.

Because both piezoelectric actuators 2,2′ engage with their transducers on both opposite flat sides of the object 16, the object 16 will not be subjected to any additional force. Guiding of the object 16 can hence be embodied in a simple manner.

FIGS. 4a to 4c and FIGS. 5a to 5c are intended solely to elucidate an interaction among a plurality of piezoelectric actuators 2,2′. Objects 16 having a very large mass can basically also be moved as a result of employing an even larger number of piezoelectric actuators 2,2′. Moreover, the piezoelectric actuators 2,2′ will in that case not have to be individually driven consecutively but can also be driven in groups. If the object 16 has a very high mass, then individual transducers 8,8′ will, owing to its mass inertia, also be displaceable if driven relatively slowly. Depending on the object 16 requiring to be moved, the number of piezoelectric actuators 2,2′, the driving thereof, and their friction surfaces 18 will hence be mutually coordinated to obtain an even movement.

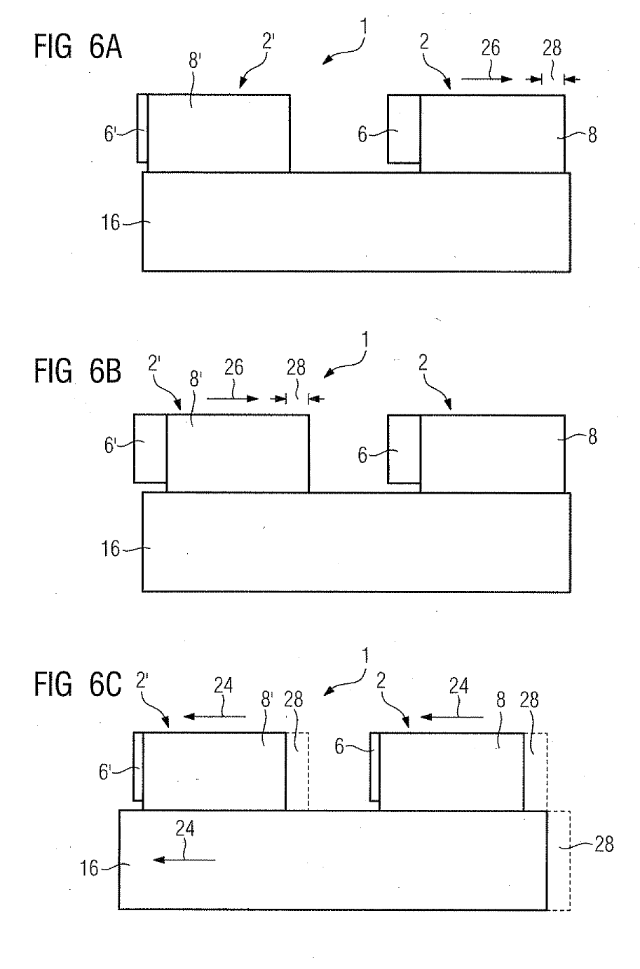

It is furthermore possible to arrange two or more piezoelectric actuators 2,2′ on one side of an object 16. According to FIG. 6a two piezoelectric actuators 2,2′ are arranged in the case of a third linear drive 1 on one of the two flat sides of an object 16. Moving of the object 16 in the direction of motion 24 proceeds according to FIGS. 4a-c. The only difference compared with FIGS. 4a-c is in the arrangement of the piezoelectric actuators 2,2′.

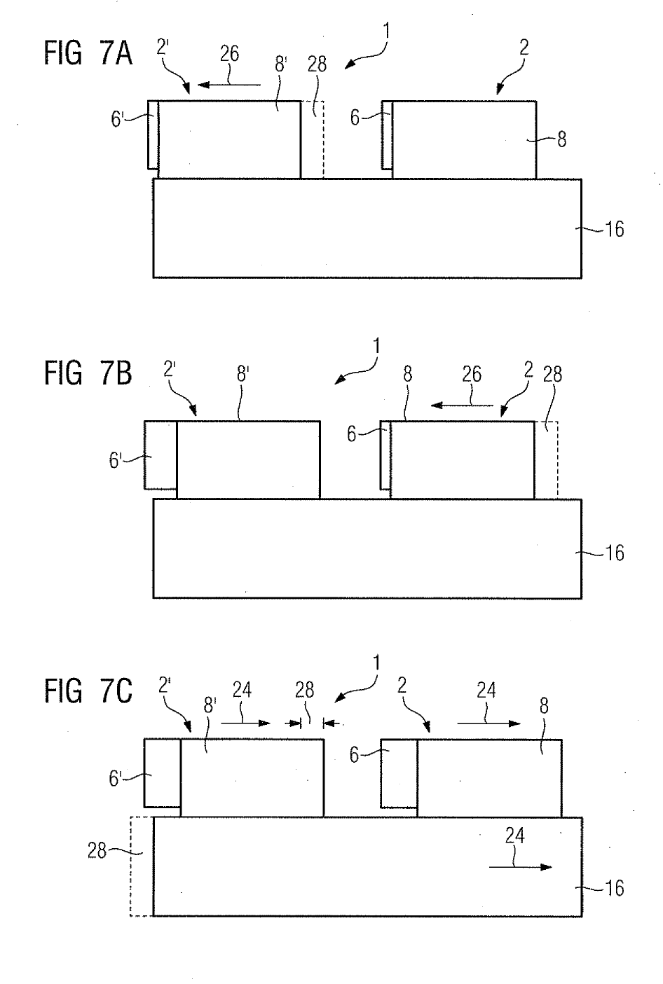

Analogously thereto, moving of the object 16 in the direction of motion counter to that shown in FIGS. 6a-c is shown in FIGS. 7a-c. Moving of the object 16 proceeds in the direction of motion 24 according to the description relating to FIGS. 5a to 5c.

Arranging a plurality of piezoelectric actuators 2,2′ on one side of the object 16 requires installation space for the piezoelectric actuators 2,2′ only on that side of the object 16. A linear drive of said type having piezoelectric actuators 2,2′ arranged on one side of the object thus makes a compact design possible; on the other hand, the static frictional forces of the transducers 8,8′ will engage only on one side of the object when the object 16 is displaced so that appropriate guiding will have to be provided for moving the object 16 smoothly in the direction of motion 24.

1.-15. (canceled)

16. A linear drive for driving a moveably mounted object, comprising:
a piezoelectric element held by a holding body;
a transducer coupled to the piezoelectric element;
a piezoelectric actuator comprising the piezoelectric element and the transducer; and
a control device that drives the piezoelectric actuator by exploiting a mass inertia of the object,
wherein the transducer is configured to move the object via a mechanical frictional force between the transducer and the object during an excursion of the piezoelectric element in a direction of motion and slide across the object in an opposite direction of motion.

17. The linear drive as claimed in claim 16, wherein the control device drives the piezoelectric actuator for moving the transducer slower in the direction of motion than in the opposite direction of motion.

18. The linear drive as claimed in claim 16, wherein the object is moved by a plurality of piezoelectric actuators.

19. The linear drive as claimed in claim 18, wherein the control device drives the piezoelectric actuators in succession.

20. The linear drive as claimed in claim 18, wherein a same number or a higher number of the piezoelectric actuators are simultaneously driven by the control device in the direction of motion than in the opposite direction of motion.

21. The linear drive as claimed in claim 16, wherein a linear guide for guiding the transducer is located between the holding body and the transducer.

22. The linear drive as claimed in claim 16, wherein the transducer is pretensioned against the holding body by an elastic element.

23. The linear drive as claimed in claim 16, wherein the holding body encompasses the piezoelectric element with the transducers like a clamp.

24. A drive unit for moving a linear drive to drive a moveably mounted object, comprising:
a piezoelectric element held by a holding body;
a transducer coupled to the piezoelectric element that transmits a friction force as a driving force to the object;
a piezoelectric actuator comprising the piezoelectric element and the transducer; and
a control device that drives the piezoelectric actuator for moving the object in a direction of motion during an excursion of the piezoelectric element via exploiting a mass inertia of the object.

25. A method for displacing a moveably mounted object, comprising:
providing a piezoelectric actuator comprising a piezoelectric element and a transducer coupled to the piezoelectric element;
transmitting a mechanical frictional force between the transducer and the object; driving the piezoelectric actuator by exploiting a mass inertia of the object;
moving the object by the transducer in a direction of motion; and
sliding the transducer across the object in an opposite direction of motion.

26. The method as claimed in claim 25, wherein the transducer is moved slower in the direction of motion than in the opposite direction of motion.

27. The method as claimed in claim 25, wherein the object is moved by a plurality of piezoelectric actuators.

28. The method as claimed in claim 27, wherein the piezoelectric actuators are driven in succession.

29. The method as claimed in claim 27, wherein a same number or a higher number of piezoelectric actuators are driven in the direction of motion than in the opposite direction of motion.

30. The method as claimed in claim 25, wherein the transducer is guided by a linear guide.
